(19) United States
(12) Patent Application Publication
(10) Pub. No.: US 2026/0343794 A1
(43) Pub. Date: Oct. 29, 2026

(54) SYSTEM AND METHOD FOR THERMAL MANAGEMENT VIA DYNAMIC FAN CONTROL

(71) Applicant: Aivres Systems Inc., Fremont, CA (US)

(72) Inventors: Hueiming CHU, New Taipei City (TW); Mingduo KAO, New Taipei City (TW)

(73) Assignee: Aivres Systems Inc., Fremont, CA (US)

(21) Appl. No.: 19/436,876

(22) Filed: Dec. 30, 2025

(51) Int. Cl. H05K 7/20

(52) U.S. Cl. CPC H05K 7/20209; H05K 7/20136

(57) ABSTRACT

A method is provided for thermal management in an electronic device through fan control. The method includes configuring one or more fans in the electronic device to operate in an intermittent mode, based on detecting an overheat event in the electronic device, adjusting the one or more fans in the intermittent mode to enhance a cooling effect, and based on the overheat event being resolved, controlling the one or more fans to return to the intermittent mode. In the intermittent mode, the one or more fans are sequentially powered in an intermittent manner.

### TECHNICAL FIELD

The disclosed embodiments relate generally to computer systems, and more particularly, to the thermal management by controlling fan modules in computer systems.

### BACKGROUND

In an electronic system such as a server system or other computer system, fans provide for cooling by dissipating heat generated during system activity. Fan power control typically relies on an uninterrupted and continuous power supply approach. This method alternates between main power and standby power sources to provide continuous power to the fans, thereby managing fan power consumption.

However, such methods are limited in functionality. They only allow for basic control, such as turning fans on or off, and lack the flexibility to adjust the number of operating fans or to selectively activate specific fans based on server temperature conditions. As a result, fans often remain active regardless of system load, leading to unnecessary power consumption even during light-load conditions. Furthermore, the continuous power supply method fails to take advantage of the residual cooling effect generated by the fans’ rotational inertia when power is cut off, thereby wasting natural cooling resources. These fan control methods are inefficient in adapting to real-time thermal demands, reduce fan lifespan, waste energy, and increase overall server operating costs.

### SUMMARY

In an exemplary embodiment, a method is provided for thermal management in an electronic device through fan control. The method includes configuring one or more fans in the electronic device to operate in an intermittent mode, based on detecting an overheat event in the electronic device, adjusting the one or more fans in the intermittent mode to enhance a cooling effect, and based on the overheat event being resolved, controlling the one or more fans to return to the intermittent mode. In the intermittent mode, the one or more fans are sequentially powered in an intermittent manner.

According to an embodiment of the method, the method further includes determining a power source between a main power and an auxiliary power for the electronic device. In certain embodiments, based on determining the main power as the power source, the method also includes configuring the one or more fans to operate in an intermittent mode associated with the main power. In certain embodiments, based on determining the main power as the power source, the method also includes based on determining the auxiliary power as the power source, configuring the one or more fans to operate in an intermittent mode associated with the auxiliary power.

According to an embodiment of the method, the method further includes detecting, in the electronic device, a region associated with the overheat event, the region corresponding to at least one first fan of the one or more fans, and switching the at least one first fan from the intermittent mode to a second intermittent mode, or switching the at least one first fan from the intermittent mode to a continuous power supply mode.

According to an embodiment of the method, the method further includes determining at least one second fan of the one or more fans, the at least one second fan located in a region surrounding the at least one first fan, and adjusting the at least one second fan in a corresponding intermittent mode to enhance the cooling effect in the detected region.

According to an embodiment of the method, the method further includes based on determining that the electronic device currently operating in peak time, switching all fans in the one or more fans from the intermittent mode to a continuous power supply mode.

According to an embodiment of the method, the peak time is dynamically updated based on learning operational patterns of the electronic device.

According to an embodiment of the method, the intermittent mode is a default intermittent mode associated with an operating status of the electronic device. The operating status is active or idle. The default intermittent mode associated with the operating status of the electronic device is dynamically updated based on learning operational patterns of the electronic device.

According to an embodiment of the method, adjusting the one or more fans in the intermittent mode to enhance the cooling effect further includes determining an urgency and severity of the overheat event, and determining, based on the urgency and severity, a cooling measure among a plurality of cooling measures.

According to an embodiment of the method, the plurality of cooling measures includes switching at least one fan of the one or more fans from the intermittent mode to another intermittent mode, switching at least one fan of the one or more fans from the intermittent mode to a continuous power supply mode, and switching all fans in the one or more fans from the intermittent mode to the continuous power supply mode.

According to an embodiment of the method, the method further includes initiating a fan control system during power-on of the electronic device, and loading settings associated with the intermittent mode.

In a further exemplary embodiment, a system is provided for thermal management in an electronic device. The system includes one or more fans and a controller. The controller is configured to configure the one or more fans in the electronic device to operate in an intermittent mode, based on detecting an overheat event in the electronic device, adjust the one or more fans in the intermittent mode to enhance a cooling effect, and based on the overheat event being resolved, control the one or more fans to return to the intermittent mode. In the intermittent mode, the one or more fans are sequentially powered in an intermittent manner.

According to an embodiment of the system, the controller is further configured to determine a power source between a main power and an auxiliary power for the electronic device. In certain embodiments, based on determining the main power as the power source, the controller is configured to configure the one or more fans to operate in an intermittent mode associated with the main power. In certain embodiments, based on determining the auxiliary power as the power source, the controller is configured to configure the one or more fans to operate in an intermittent mode associated with the auxiliary power.

According to an embodiment of the system, the controller is further configured to detect, in the electronic device, a region associated with the overheat event, the region corresponding to at least one first fan of the one or more fans, and switch the at least one first fan from the intermittent mode to a second intermittent mode, or switch the at least one first fan from the intermittent mode to a continuous power supply mode.

According to an embodiment of the system, the controller is further configured to determine at least one second fan of the one or more fans, the at least one second fan located in a region surrounding the at least one first fan, and adjust the at least one second fan in a corresponding intermittent mode to enhance the cooling effect in the detected region.

According to an embodiment of the system, the controller is further configured to switch, based on determining that the electronic device currently operating in peak time, all fans in the one or more fans from the intermittent mode to a continuous power supply mode.

According to an embodiment of the system, the peak time is dynamically updated based on learning operational patterns of the electronic device.

According to an embodiment of the system, the intermittent mode is a default intermittent mode associated with an operating status of the electronic device. The operating status is active or idle. The default intermittent mode associated with the operating status of the electronic device is dynamically updated based on learning operational patterns of the electronic device.

According to an embodiment of the system, adjusting the one or more fans in the intermittent mode to enhance the cooling effect further includes determining an urgency and severity of the overheat event, and determining, based on the urgency and severity, a cooling measure among a plurality of cooling measures.

According to an embodiment of the system, the plurality of cooling measures includes switching at least one fan of the one or more fans from the intermittent mode to another intermittent mode, switching at least one fan of the one or more fans from the intermittent mode to a continuous power supply mode, and switching all fans in the one or more fans from the intermittent mode to the continuous power supply mode.

In yet a further exemplary embodiment, a non-transitory computer-readable medium having stored thereon a set of instructions for thermal management in an electronic device is provided. The set of instructions, if performed by one or more processors, cause the one or more processors to perform configuring one or more fans in the electronic device to operate in an intermittent mode, based on detecting an overheat event in the electronic device, adjusting the one or more fans in the intermittent mode to enhance a cooling effect, and based on the overheat event being resolved, controlling the one or more fans to return to the intermittent mode. In the intermittent mode, the one or more fans are sequentially powered in an intermittent manner.

### BRIEF DESCRIPTION OF THE DRAWINGS

Systems and methods for thermal management are described in detail below with reference to the attached drawing figures, wherein:

FIG. 1 illustrates a block diagram of a system, according to one or more embodiments of the present disclosure.

FIG. 2 illustrates a block diagram of a fan control system, according to one or more embodiments of the present disclosure.

FIG. 3A illustrates an example fan table, according to one or more embodiments of the present disclosure.

FIG. 3B illustrates an example control signal table for an intermittent mode, according to one or more embodiments of the present disclosure.

FIG. 4 illustrates a flowchart of a method for thermal management, according to one or more embodiments of the present disclosure.

FIG. 5 illustrates a flow diagram of a method for thermal management, according to one or more embodiments of the present disclosure.

FIG. 6 illustrates a flowchart of a method for updating the fan control system, according to one or more embodiments of the present disclosure.

### DETAILED DESCRIPTION

The following detailed description is merely exemplary in nature and is not intended to limit the disclosure or the application and uses of disclosed embodiments and methods. Furthermore, there is no intention to be bound by any expressed or implied theory presented in the preceding background, summary, brief description of the drawings or the description that follows.

Systems and methods are disclosed herein for thermal management in computer systems. In at least one embodiment, a fan control scheme is implemented using one or more control units/devices, such as a complex programmable logic device (CPLD). The fan control scheme employs one or more scanning-based sequential power supply strategies (intermittent modes) to achieve energy savings. In addition, the fan control scheme enables dynamic adjustment of the power supply modes based on various conditions. For example, the fan control scheme may adjust the current fan power supply mode after evaluating an overheat event, such as by determining its priority and/or urgency. This approach ensures that urgent and severe overheating events are addressed immediately, while power-saving measures are applied only when appropriate. In at least one embodiment, the fan control scheme may be updated based on operational patterns of the system (e.g., the server) learned from historical behavior. For example, routine intensive use of the system during certain time periods may be identified and designated as “peak time.” The fan control scheme may utilize this information to apply different strategies during the peak time to more effectively address overheat events.

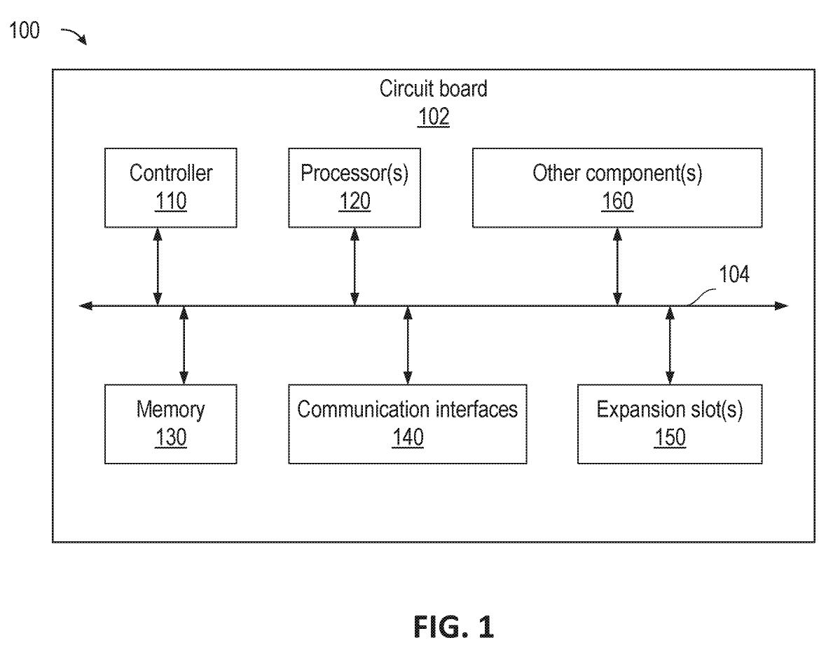

FIG. 1 illustrates a block diagram of a system 100, e.g., computer system or server or other electronic device, suitable for use in implementing embodiments of the present disclosure. The arrangements described herein, including this example, are provided for illustrative purposes only. Alternative configurations and components may be used in place of or in addition to those shown, and some components may be omitted entirely. Many of the elements described are functional in nature and can be implemented as standalone or distributed components or devices, either independently or in combination with other components, and located in various configurations. The functions discussed may be executed through hardware, firmware, and/or software, with processes typically performed by a processor executing instructions stored in memory. Those skilled in the art will recognize that any system capable of performing the operations of the system 100 falls within the scope and intent of the disclosed embodiments. The system 100 can be housed in a rack-mounted chassis designed for optimal airflow and cooling, ensuring efficient heat dissipation during operation. A person skilled in the art will recognize that the systems and methods described herein can be used with electronic devices other than computer and server systems.

The system 100 includes one or more circuit boards 102, e.g., a motherboard, that may carry various components, including hardware, firmware, and/or software, which may be integrated with, attached to, connected to, or in communication with the motherboard. As shown in FIG. 1A, the circuit board 102 carries at least one controller 110, such as a baseboard management controller (BMC), one or more processors 120, memory 130, communication interfaces 140, one or more expansion slots 150, and one or more other components 160. Such components and the circuit board 102 can communicate with one another through a bus 104, which may be integrated into the circuit board 102.

Processor(s) 120 may be configured to perform the operations in accordance with the instructions stored in memory 130. In certain embodiments, the memory 130 may be integral to the processor(s) 120. In other embodiments, the memory may in whole or in part be separate from the processor(s) 120. Processor(s) 120 may include any appropriate type of general-purpose or special-purpose microprocessor (e.g., a central processing unit (CPU) or graphics processing unit (GPU), respectively), digital signal processor, microcontroller, or the like. Memory 130 may be configured to store computer-readable instructions that, when executed by processor(s) 120, can cause processor(s) 120 to perform various operations disclosed herein and/or store data relating thereto.

Memory 130 may be any non-transitory type of mass storage, such as volatile or non-volatile, magnetic, semiconductor-based, tape-based, optical, removable, non-removable, or other type of storage device or tangible computer-readable medium including, but not limited to, a read-only memory (“ROM”), an electrical erasable programmable ROM (EEPROM), a flash memory, a dynamic random-access memory (“RAM”), and/or a static RAM. In certain embodiments, memory 130 may include multiple storage devices of various types.

Communication interfaces 140 may be configured to communicate information between system 100 and other devices or systems. For example, communication interfaces 140 may include an integrated services digital network (“ISDN”) card, a cable modem, a satellite modem, or a modem to provide a data communication connection. As another example, communication interfaces 140 may include a local area network (“LAN”) card to provide a data communication connection to a compatible LAN. As a further example, communication interfaces 140 may include a high-speed network adapter such as a fiber optic network adaptor, 10G Ethernet adaptor, or the like. Wireless links can also be implemented by communication interfaces 140. In such an implementation, communication interfaces 140 can send and receive electrical, electromagnetic, or optical signals that carry digital data streams representing various types of information via a network. The network can typically include a cellular communication network, a Wireless Local Area Network (“WLAN”), a Wide Area Network (“WAN”), or the like.

Controller 110, e.g., BMC, may include a processing unit, associated memory, and communication interfaces, and is configured to monitor and manage the system’s hardware components among other things. Controller 110 handles tasks such as remote system management, including hardware health monitoring, system event logging, and power control. Controller 110 can operate independently of the system’s 100 main processor (e.g., processor(s) 120), allowing for out-of-band management. Controller 110 may in certain embodiments facilitate communication with various sensors (e.g., other component(s) 160) on the circuit board 102 to track temperature, fan speed, voltage levels, and other critical parameters. Additionally, the controller 110 may include network interfaces and/or operate in conjunction with communication interfaces 140 to enable remote access for system administrators, providing a way to perform diagnostic tasks, power cycling, and firmware updates.

The expansion slot(s) 150 on the circuit board 102 may be used for connecting additional peripherals, such as GPUs, network cards, and more.

The other components 160 can include integrated components, replaceable components, and other suitable components. For example, these components may include but are not limited to sensors, cooling devices, power supply modules (and/or connectors), clock generators, and more.

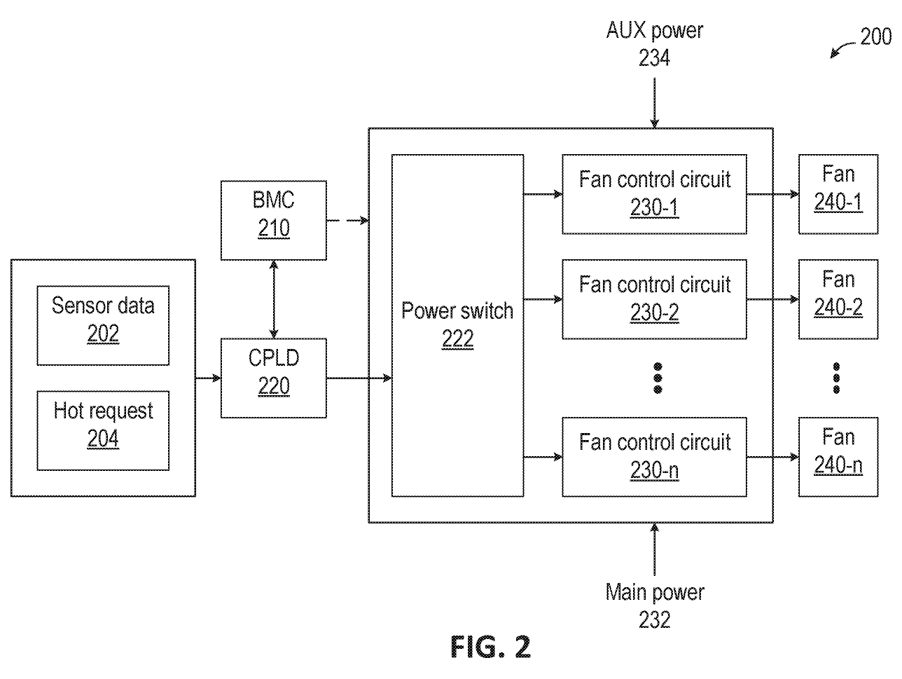

FIG. 2 illustrates a block diagram of a fan control system 200, according to one or more embodiments of the present disclosure. In certain embodiments, the fan control system 200 is implemented in the system 100. For example, the fan control system 200 executes the fan control scheme disclosed herein to facilitate thermal management of system 100. In certain embodiments, the components as shown in FIG. 1 and/or other additional suitable components may be implemented to facilitate the functionalities disclosed herein. In other embodiments, the fan control system 200 may be separate from the system 100.

As shown in FIG. 2, the fan control system 200 utilizes a BMC 210 and/or a CPLD 220 to control power supply to a plurality of fans 240-1, 240-2, …, 240-n. It will be understood that, although BMC 210 and CPLD 220 are described by way of example, other controllers (e.g., controller 110 and logic devices may be employed. In the illustrated example, each fan 240 is connected to an independent fan control circuit (e.g., fan control circuits 230-1, 230-2, …, 230-n), which in turn is communicatively connected to the BMC 210 and/or the CPLD 220. This arrangement allows transmission of one or more control signals to a given fan control circuit 230 to control or adjust the operation of its corresponding fan 240. It should be noted, however, that other configurations between the fan control circuit(s) 230 and the fan(s) 240 may also be implemented. For example, a single fan control circuit may be connected to multiple fans, or multiple fan control circuits may be connected to a single fan. The fan control circuits 230-1, 230-2, …, 230-n may receive one or more control signals from the BMC 210 and/or the CPLD 220 to control or adjust the operation of the corresponding fans 240-1, 240-2, …, 240-n.

In at least one embodiment, a power switch 222 is connected between the CPLD 220 and the fan control circuits 230-1, 230-2, …, 230-n. The CPLD 220 may operate in conjunction with the power switch 222 to sequentially supply power to the fans 240-1, 240-2, …, 240-n through the corresponding fan control circuits 230-1, 230-2, …, 230-n. Additionally and/or alternatively, the CPLD 220 and the power switch 222 may operate together to enable other flexible operation, such as selecting only a subset of the fans for operation.

A CPLD is a type of programmable logic device used in computer systems and embedded hardware to perform custom digital logic functions. In at least one embodiment, the CPLD 220 is configured to control the fans and/or fan groups in the server. For example, the CPLD 220 may be configured to control the manner in which power is delivered, such as enabling or disabling power, providing continuous power, or supplying power intermittently according to a specific pattern (e.g., in intermittent modes).

It should be understood by a person skilled in the art that the fan control may be facilitated by the CPLD 220, the BMC 210, or through a hybrid configuration. Additionally, other configurations are also possible. For example, power regulation may be performed by other controllers or microprocessor chips. In this example, a separate fan control circuit is provided as one possible implementation; however, similar functionality may also be achieved without a separate fan control circuit—for example, by configuring the CPLD 220 or BMC 210 to directly send individual control signals to each fan module. In certain embodiments, the fan control circuit may be integrated in a fan module.

The fans 240-1, 240-2, …, 240-n may be powered by one or more power sources, including for example a main power source (or main power 232) and an auxiliary power source (or AUX power 234). The main power 232 may be configured to provide power during normal system operation, while the AUX power 234 (e.g., standby or backup power) may be configured to supply power when the main power is unavailable or the system is in a low-power or standby state. In certain embodiments, the AUX power ensures that critical components, such as monitoring circuits, fans, and control logic (e.g., CPLD or BMC), can continue to operate or maintain readiness even when the main system is powered down. This enables continued thermal monitoring and controlled fan operation during standby conditions, contributing to system reliability and energy efficiency.

In at least one embodiment, the CPLD 220 is configured to select a power source between the main power 232 and the AUX power 234 to power the fans 240-1, 240-2, …, 240-n, as well as other suitable components (e.g., the fan power control circuits 230-1, 230-2, …, 230-n) in the fan control system 200.

In at least one embodiment, the BMC 210 and CPLD 220 may form a control hierarchy in which the BMC 210 instructs the CPLD 220 to perform specific control operations on the fan(s). For example, the BMC 210 may determine the appropriate fan speed based on temperature sensor readings and issue high-level control signals, while the CPLD 220 carries out the actual fan power gating or sequencing to ensure that power is delivered or removed in a safe and timely manner.

In at least one embodiment, the fan control system 200, such as the BMC 210 and/or the CPLD 220, obtains sensor data 202 indicating temperature status in various regions in the actual device. For example, a server device may be divided into different regions for thermal management, with each region equipped with one or more temperature sensors to monitor the real-time temperature. The sensor data may be obtained periodically—for example, based on a predefined periodicity or sampling rate—and/or through specific requests initiated by the user or other components in the device (e.g., one or more processors, BMC 210, CPLD 220, etc.).

In at least one embodiment, the fan control system 200, such as the BMC 210 and/or the CPLD 220, is configured to obtain a “hot request,” which is a signal indicating that the device or a specific component has reached a critical temperature threshold. Upon receiving this hot request, the fan control system 200 can initiate appropriate cooling measures, such as increasing fan speed or activating additional cooling resources, to prevent overheating and maintain optimal thermal conditions within the server. For example, the hot request may include a CPU processor hot request (denoted, for example, as “PROCHOT”), which indicates a temperature issue in the CPU process (e.g., the processer(s) 120 in the system 100), a memory hot request (denoted, for example, as “MEMHOT”), which indicates a temperature issue in the memory (e.g., the memory 130 in the system 100), or other similar temperature-related alerts.

In certain embodiments, the CPLD 220 is, or is integrated within, a voltage control module (e.g., a voltage control circuitry) that is configured to adjust the voltage outputs for controlling the fan power supply.

In certain embodiments, the CPLD 220 stores specific information in an internal memory within the CPLD 220 and/or in a memory coupled thereto. This information may take various forms, such as tables, lists, arrays, metadata, and so forth, and may include multiple types of data, such as component identifiers (e.g., component codes), identifiers (e.g., codes) for the corresponding control blocks, records or logs of the current voltage sequencing status, counts of hot requests received, fan drive voltage control durations, fan voltage output states, and other suitable information. Furthermore, instructions that implement the methods disclosed herein, are stored in the memory, enabling the CPLD 220 to dynamically adjust the power delivery to the fans.

In thermal management, the fans in a device (e.g., a server or other electronic device) may be arranged in a layout that corresponds to specific cooling zones or airflow paths. Each fan may be uniquely identified by a component code stored in the system, enabling precise monitoring and control. In certain embodiments, the fans may be associated with respective control blocks, which govern the operation of the fans, such as voltage output, speed control, and activation timing. Each control block may likewise be assigned a unique block code, allowing the control system (e.g., the BMC 210 or CPLD 220) to map fan identifiers to their corresponding control blocks for coordinated thermal management actions.

In certain embodiments, information such as the component codes for identifying individual fans and/or the identifiers for the corresponding control blocks is obtained by the CPLD 220 during various stages of system operation. For example, during system initialization or reset, the CPLD 220 may retrieve the information from an internal memory, a memory coupled thereto, or from other system components (e.g., via a system management bus) to configure its fan control logic prior to normal operation. In at least one embodiment, the CPLD 220 receives such information from the BMC 210, which collects the data from the circuit board 102 during system initialization, power-on self-test (POST), or periodic system scans. The CPLD 220 may also update the information during runtime, for example, upon detection of a hardware change (e.g., replacement of a fan or fan module), thereby ensuring that the fan control operations remain synchronized with the current hardware configuration.

In certain embodiments, an inertia test may be performed for the fans to determine a relative inertial force, which, together with the fan’s mass and aerodynamic principles, may be used to calculate an inertia rotation time. A wind force test may also be conducted to determine an effective cooling range (e.g., heat dissipation range) of the fan. Additionally, layout information of the fans within the server may be obtained, the layout information being usable in conjunction with the effective cooling range to evaluate and optimize airflow distribution and thermal management performance of the server. Such information may be utilized to determine an intermittent mode for a specific fan or fan group. An intermittent mode for a fan defines parameters related to the fan’s intermittent voltage output.

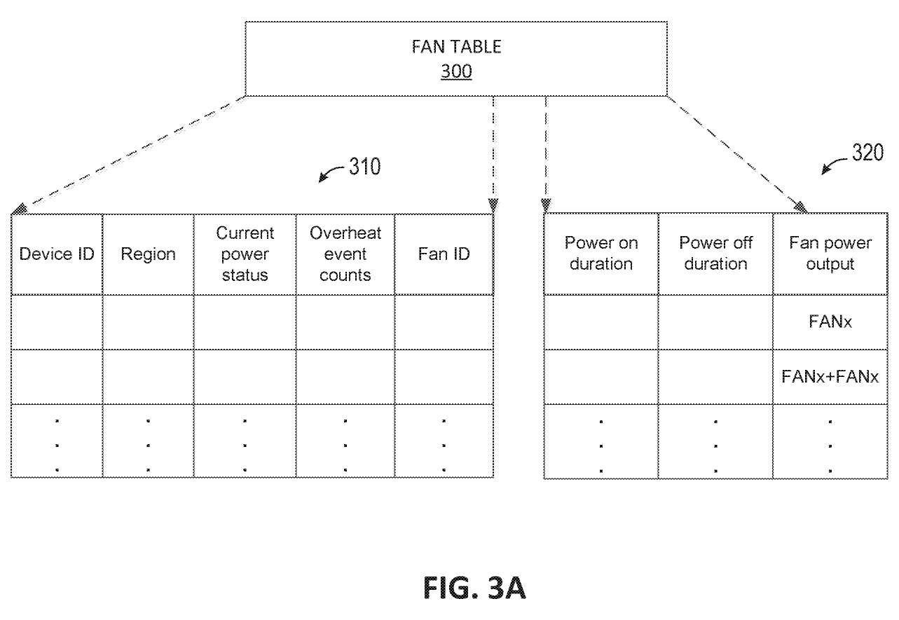

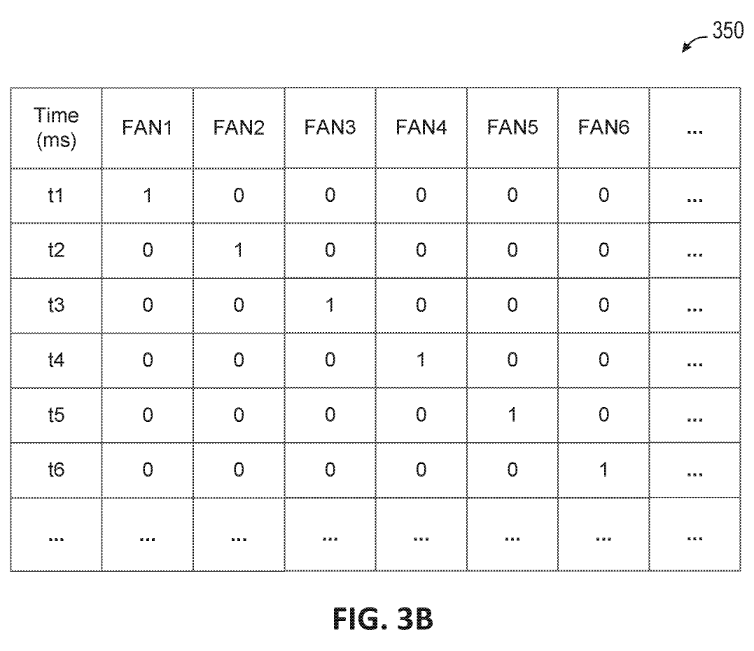

FIG. 3A illustrates an example fan table 300, according to one or more embodiments of the present disclosure. The fan table 300 represents an example of data that may be stored and utilized by the CPLD 220 to support various functionalities disclosed herein, such as controlling the operation of the fans in a device.

In certain embodiments, the fan table 300 includes multiple tables storing different types of information, including, for example, table 310 and table 320 as shown in FIG. 3. Additionally, and/or alternatively, the information in tables 310 and 320 may be organized as subcolumns within a single larger table. These are, of course, provided by way of example. Any suitable number of tables may be employed.

In table 310, “device ID” is a unique identifier for each fan control object (or fan control target), such as a hardware device number, “region” indicates the physical or logical area where the fan is located, such as a specific chassis area or a particular board area, “current power status” represents the current operating state (e.g., idle or active) of the system’s power domain, “overheat event counts” tracks the number of consecutive occurrences of a certain condition or event, such as consecutive over-temperature events, and “fan ID” represents the fan’s identifier, for example, FAN1, FAN2, and so on. In at least one embodiment, the “overheat event counts” records the number of events within a predefined time period (e.g., 24 hours) and may be reset either based on predefined conditions (such as the expiration of the time period) or upon user request. Table 320 may store operational settings associated with an intermittent mode for one or more fans. In certain embodiments, an intermittent mode may be defined by a periodic square waveform having predefined on and off durations (e.g., defined by “power on duration” and “power off duration,” respectively). Each intermittent mode may be associated with one or more fans. In certain embodiments, “fan power output” may indicate additional fan output control parameters, such as pulse width modulation (PWM) duty cycle or percentage of rotational speed associated with one or more fans. As shown in table 320, operational settings may be defined for individual fans (e.g., denoted as “FANx”) and/or for groups of fans (e.g., denoted as “FANx+FANx”).

However, it will be understood that other configurations may be used to store information for identifying components in a device and/or to define intermittent mode settings, such as using different table formats, data arrangements, waveform patterns, or timing parameters.

Certain information in the fan table 300, such as the overheat event counts in table 310, may be utilized by the fan control system 200 to dynamically adjust the fan control scheme. For example, the fan control system 200 may assess the urgency and/or severity of an overheat event based on whether the overheat event counts exceed a threshold value and/or based on the priority of the fan control target.

In at least one embodiment, the fan table 300 may store logs recording data related to the system’s operational behavior. This historical data may be accessed by, or transmitted to, a processor for further analysis. For example, as detailed below, the processor may perform method 600 on the collected data to update the fan control scheme based on learned patterns. In at least one embodiment, the settings in table 320 may be adjusted based on the updated fan control scheme. Information in the fan table 300 may be modified during use to accommodate changes in configuration of the system 100 or for other reasons.

FIG. 3B illustrates an example control signal table 350 for an intermittent mode, according to one or more embodiments of the present disclosure. In at least one embodiment, the control signal table 350 is included in the fan table 300 in FIG. 3A. In at least one embodiment, data in the control signal table 350 may be determined by the CPLD 220 (the BMC 210, or other suitable processors) based on the fan table 300 and/or other suitable information. In other embodiments, the data in the control signal table 350 may be user configurable.

In FIG. 3B, FAN1 through FAN6 represent six fans. The power supply is divided into multiple time periods, with t1 through t6 denoting the respective starting times of these periods. During each time period, only one fan is supplied with power, indicated by a logic “1” signal. The remaining fans are not powered, as indicated by a logic “0” signal, and may continue rotating due to inertia. For example, the CPLD 220 may operate in conjunction with the power switch 222 to sequentially supply power to the multiple fans (e.g., FAN1 through FAN6). The CPLD 220 may repeatedly supply power to FAN1 through FAN6 in sequence, thereby causing the fans to operate in a specific intermittent mode. In certain embodiments, the CPLD 220 may supply power to FAN1 through FAN6 in different intermittent modes based on different control signals (e.g., represented by control signal tables). For example, these control signal tables may specify parameters such as which fans are powered, the duration of each time period, and other operational settings.

In certain embodiments, during the time period beginning at t1, FAN1 may be powered for 1 millisecond (ms) and remain unpowered for the time periods beginning at t2 through t6. Subsequently, during the time period beginning at t2, FAN2 may be powered for 1ms and remain unpowered for the time periods beginning at t3 through t6. This sequence may then be repeated in the same manner for the remaining fans. These are provided by way of example. It will be understood by a person skilled in the art that the same principle may be applied to sequentially power any number of fans, and/or to power two, three, four, or more fans simultaneously.

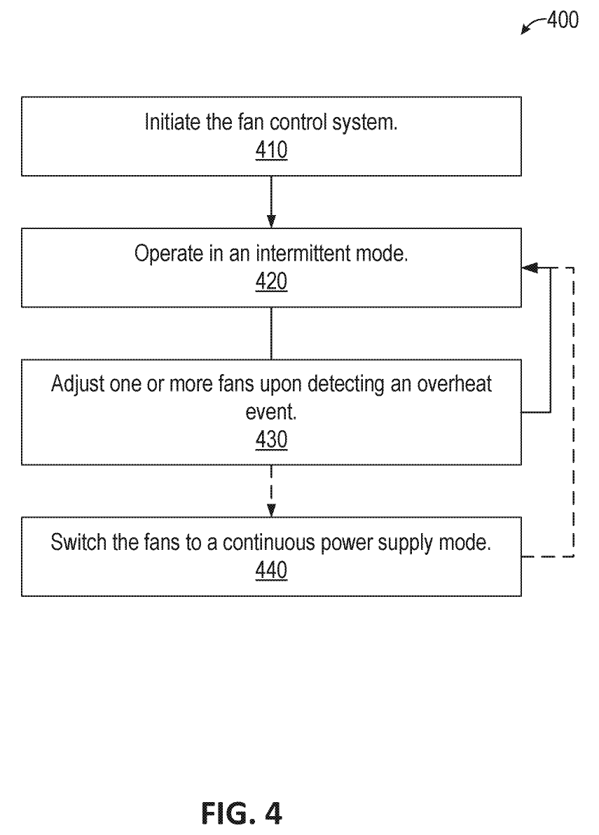

FIG. 4 illustrates a flowchart of a method 400 for thermal management, according to one or more embodiments of the present disclosure. Method 400 may be performed by the fan control system 200 as illustrated in FIG. 2. Method 400 may be performed alone or in combination with other processes in the present disclosure. It will be recognized that method 400 may be performed in any suitable environment and in any suitable order except where otherwise apparent. Alternative stages may be performed instead of or in addition to those shown, and some stages may be omitted entirely.

At stage 410, the fan control system is initiated. For example, upon power-on (or boot-up) of a system 100 (e.g., a server), relevant settings, such as information included in the fan table, are loaded into the CPLD 220 or a memory coupled thereto, with the initial operating mode set to continuous power supply. Once the system powers on, the appropriate power domain—such as AUX power or main power—is selected.

In at least one embodiment, the fan control system obtains suitable information, such as the table 310 and/or the control signal table 350, during system initiation. Additionally, and/or alternatively, the fan control system may receive instructions for executing the methods disclosed herein at this time. However, it will be understood that the relevant information and/or instructions may also be obtained by the fan control system at other times during operation, such as during periodic system updates, in response to user commands or environmental changes, upon detection of hardware modifications, or via communication with external management entities.

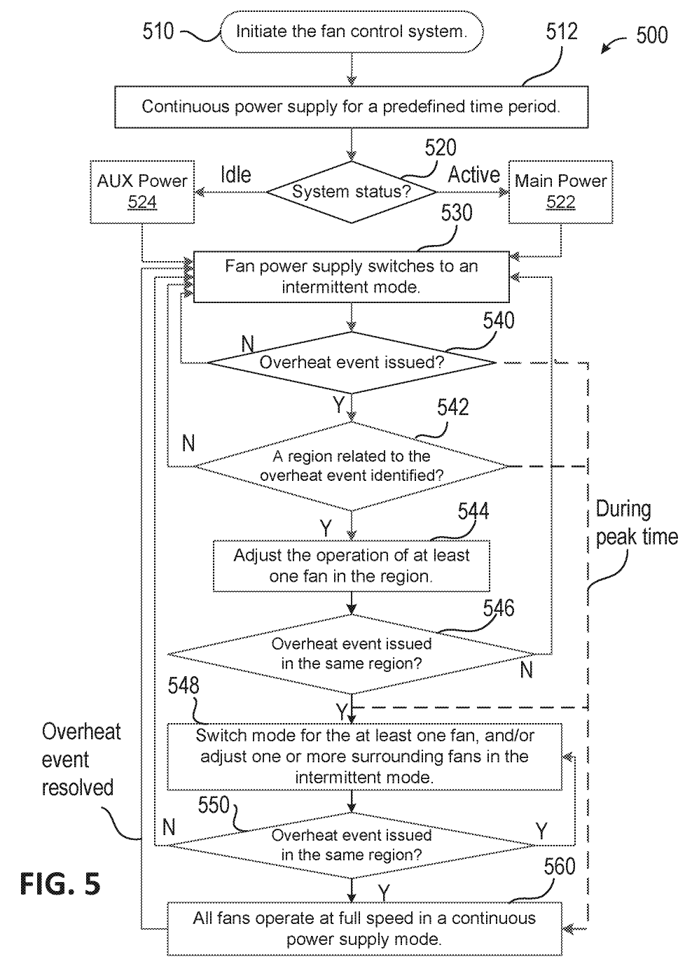

At stage 420, the fan control system operates in an intermittent mode. In at least one embodiment, the fan control system may determine an intermittent mode based on the current power domain (e.g., the AUX power or the main power). In at least one embodiment, the fan control system may initially select a default intermittent mode. The fan control system may then switch to another intermittent mode in response to a request or upon detecting a specific operational status of the system (e.g., the server). For example, the AUX power and the main power may be associated with different default intermittent modes. The different default intermittent modes associated with the AUX power and the main power may differ in various parameters, such as the number of fans enabled, fan speed, power on/off duration, or other suitable parameters. The default intermittent mode associated with the main power may provide better cooling for the overall server system or for a specific region (e.g., the processor(s) and/or memory) compared to the default intermittent mode associated with the AUX power. For example, as discussed with respect to the method 500 in FIG. 5, the default intermittent mode may affect stage 530, in which the fan control system determines, based on the current power domain, a fallback fan power mode (e.g., the default intermittent mode associated with the determined power domain).

At stage 430, the fan control system adjusts one or more fans upon detecting an overheat event. In at least on embodiment, the fan control system may detect an overheat event, for example, based on sensor data 202 or a hot request 204. The fan control system may adjust the one or more fans to enhance a cooling effect in the system. For example, the one or more fans may be adjusted to operate at a higher speed, to be oriented toward a detected overheat region, or to otherwise optimize cooling performance.

The fan control system may implement various cooling measures depending on different scenarios. In at least one embodiment, the fan control system adjusts one or more fans by switching from a first intermittent mode to a second intermittent mode. The second intermittent mode may provide improved cooling compared to the first intermittent mode, for example, by powering an increased number of fans, increasing fan speed, extending the power on duration, reducing the power off duration, or other suitable adjustments. In some embodiments, the fan control system may switch one or more fans to a continuous power supply mode. Additionally and/or alternatively, the fan control system may coordinate operation of fans from surrounding regions to assist with heat dissipation in the area affected by the overheat event.

Optionally, at stage 440, the fan control system terminates the intermittent mode for all fans and switches them to a continuous power supply mode. In at least one embodiment, the fan control system may switch the fans to a mode in which the fans operate at full capacity, thereby enhancing heat dissipation within the system.

At stage 430 or 440, the fan control system may return to the intermittent mode at stage 420 upon determining that the overheat event has been cleared or resolved.

FIG. 5 illustrates a flow diagram of a method 500 for thermal management, according to one or more embodiments of the present disclosure. Method 500 may be performed by the fan control system 200 as illustrated in FIG. 2, which is implemented in a system 100 as shown in FIG. 1. Method 500 may be performed alone or in combination with other processes in the present disclosure. It will be recognized that method 500 may be performed in any suitable environment and in any suitable order except where otherwise apparent. Alternative stages may be performed instead of or in addition to those shown, and some stages may be omitted entirely.

In the illustrated example, the fan control system is utilized to perform thermal management in a system (e.g., server system). Although described in the context of a server system, it will be understood that the fan control system may be implemented in any type of suitable electronic devices.

At stage 510, the fan control system is initiated. For example, during power-on (or boot-up) of the server system, the fan control system (e.g., the CPLD 220) is loaded with fan table settings. In at least one embodiment, during initiation, the fan control system may set the fan power supply to a continuous power supply mode for a predefined time period.

At stage 512, the fan control system operates in the continuous power supply mode for the predefined time period. For example, after the predefined time period, the server completes the power-on (or boot-up) process and enters a stable operating mode, in which all subsystems (e.g., the processors, memory, etc.) are fully initialized, operational parameters are stabilized, and the server system can reliably perform its intended computing and processing tasks.

At stage 520, the fan control system determines a status (e.g., an operating status) of the server system. For example, the fan control system may select the AUX power (at stage 524) when the server is in idle status or select the main power (at stage 522) when the server is in an active status.

In certain embodiments, the selection of the power may be determined based on the overall power consumption of the system. For example, when no cooling is required in a specific operational state (e.g., a “soft off” state), only the AUX power voltage input may be provided; conversely, when cooling is required, the main power may be used. This configuration enables an optimal power-saving mode, and the control may be implemented via the CPLD.

At stage 530, the fan control system switches the fan power supply to an intermittent mode. For example, the intermittent mode is determined and/or executed by the CPLD 220 based on the fan table 300 and/or the control signal table 350. Similar to stage 420 of method 400, the fan control system may first select a default intermittent mode based on a specific power domain (e.g., AUX power or main power).

At stage 540, the fan control system monitors for an overheat event. In at least one embodiment, the fan control system monitors the thermal status within the server based on sensor data 202 and/or hot requests 204.

In at least one embodiment, upon occurrence of an overheat event, the fan control system continuously monitors whether the conditions to adjust the fan control mode are met. If the overheat condition is cleared within a predefined time period, the current fan control mode is maintained. For example, the fan control system returns to stage 530. If the condition persists beyond the time period, the fan control system proceeds to the next stage.

In at least one embodiment, the fan control system proceeds to stage 542 to identify the region associated with the overheat event. For example, the system may determine the component that transmitted the hot request 204 and/or the region where the sensor detected the overheat condition based on the sensor data 202.

At stage 544, the fan control system adjusts the operation of at least one fan in the detected region. For example, the fan control system may switch the at least one fan from a first (e.g., the current) intermittent mode to a second (or different) intermittent mode to achieve an improved cooling effect.

At stage 546, the fan control system monitors whether the overheat event still exists in the same region. For example, the fan control system may monitor whether the overheat event issued at stage 540 has been cleared and/or whether another overheat event has been issued for the same region.

At stage 548, the fan control system switches at least one fan in the detected region to the continuous power supply mode. Additionally and/or alternatively, the fan control system adjusts one or more surrounding fans to a different intermittent mode (which may be the same or different from the second intermittent mode). In certain embodiments, the fan control system is loaded with a plurality of intermittent modes at stage 510, which differ in various parameters for control fan operation and may provide varying levels of cooling. For example, the different intermittent modes may may offer incremental improvements for the overall system or for a specific region.

At stage 550, the fan control system monitors whether the overheat event still exists in the same region. Similar to stage 546, the fan control system may monitor whether the overheat event issued at stage 540 or 546 has been cleared and/or whether another overheat event has been issued for the same region.

In at least one embodiment, similarly to stage 540, in stages 542, 546, and/or 550, the fan control system may continuously monitor whether the conditions to adjust the fan control mode are met. If the overheat condition is cleared within a predefined time period, the current fan control mode is maintained. For example, the fan control system returns to stage 530. If the condition persists beyond the predefined time period, the fan control system proceeds to the next stage.

At stage 560, the fan control system terminates the intermittent mode for all fans within the server and controls them to operate at full speed in a continuous power supply mode. This stage may be triggered when the fan control system determines that the overheat event persists and/or when a specific condition is met. For example, when the fan control system detects an overheat event at stage 540 and concurrently determines that the server is operating during a “peak time,” the system may proceed directly to stage 560 to achieve the most efficient cooling effect. The “peak time” may be predetermined based on behavioral patterns of the server learned from historical data, user preference settings, and/or other relevant information.

In certain embodiments, the fan control system 200 may dynamically determine whether to skip any of stages 542–550, for example, based on the urgency and severity of the overheating event.

In at least one embodiment, the fan control system incorporates a fan failure control scheme. For example, the fan control system may employ the CPLD 220 to read the fan speed feedback (e.g., via a tachometer (TACH) line) and compare it with the supply voltage. If an abnormal speed is detected or the TACH signal is not returned, the system may switch to a backup fan or extend the operating time of surrounding fans.

For example, when FAN1 fails, the surrounding fans, such as FAN2 and/or FAN3, may be controlled to provide enhanced cooling according to the thermal zone originally assigned to FAN1. In at least one embodiment, FAN2 and/or FAN3 may increase the frequency of power supply cycles (e.g., shorten the power off duration) to cover the area handled by FAN1. This arrangement helps prevent cooling blind spots caused by the failure of a single fan and improves the system’s fault tolerance.

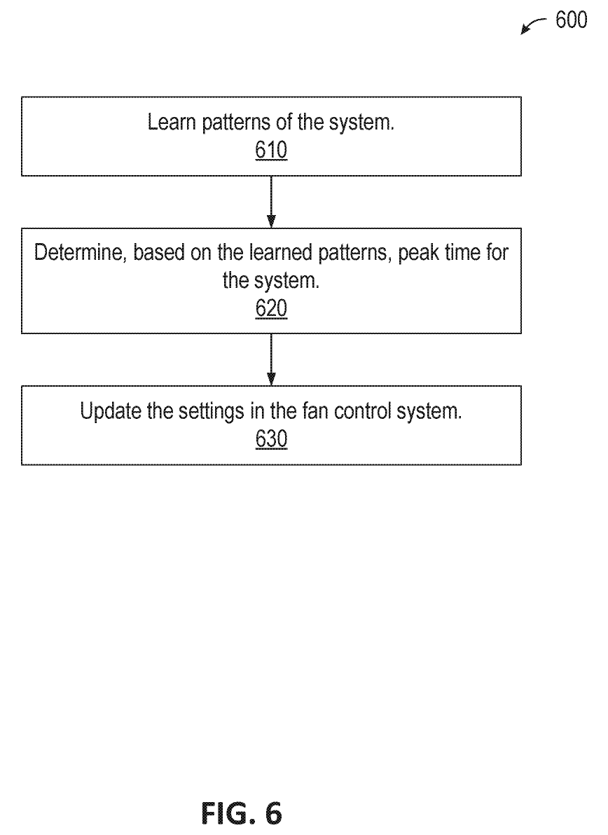

FIG. 6 illustrates a flowchart of a method 600 for updating the fan control system, according to one or more embodiments of the present disclosure. Method 600 may be performed by a processor using data collected from system 100, as shown in FIG. 1, to update the fan control system 200 implemented therein. Updating may occur automatically or as a result of a user request. The processor may be included within system 100 or coupled thereto. Method 600 may be performed alone or in combination with other processes in the present disclosure. It will be recognized that method 600 may be performed in any suitable environment and in any suitable order except where otherwise apparent. Alternative stages may be performed instead of or in addition to those shown, and some stages may be omitted entirely.

At stage 610, the processor learns patterns of the system 100. For example, the processor learns operational patterns of system 100 based on historical data including system temperature, load, fan power consumption trends, and the like. In at least one embodiment, such data is collected by the CPLD 220 and/or the BMC 210 in the fan control system 200 that is implemented in the system 100.

At stage 620, the processor determines, based on the learned patterns, peak time for the system 100.

In at least one embodiment, the processor utilizes curve fitting and self-learning techniques (e.g., using neural network models) to optimize control settings for cooling and energy savings. For example, the processor may analyze historical operating temperature, load, and fan power consumption data to identify patterns, such as periods of intensive cooling control that correspond to peak usage time (or peak time) of the system 100.

At stage 630, the processor updates the settings in the fan control system 200. For example, the processor may transmit the identified peak time information to the CPLD 220 (e.g., via the BMC 210). In certain embodiments, the peak time information is stored in the fan table 300. Accordingly, when performing stage 540 of the method 500, the fan control system 200 may determine whether an overheat event occurs during peak time. If so, the fan control system 200 may automatically switch from an intermittent power supply mode (or intermittent mode) to a continuous power supply mode (e.g., to stage 560), thereby enabling the fans to operate at maximum cooling capacity to prevent performance degradation due to overheating.

In at least one embodiment, the processor recognizes recurring peak time periods based on the historical data. For example, the processor may determine that the peak time occurs every Saturday and adjust the cooling strategy accordingly. The cooling mode may be further refined to specific hours within a day, thereby balancing high performance with energy efficiency and contributing to an extended server lifespan.

In at least one embodiment, the processor determines adjustments to one or more default intermittent modes based on the acquired learning, and updates the corresponding settings in the fan control system.

It is noted that the techniques described herein may be embodied in executable instructions stored in a non-transitory computer readable medium for use by or in connection with a processor-based instruction execution machine, system, apparatus, or device. It will be appreciated by those skilled in the art that, for some embodiments, various types of computer-readable media can be included for storing data. As used herein, a “computer-readable medium” includes one or more of any suitable media for storing the executable instructions of a computer program such that the instruction execution machine, system, apparatus, or device may read (or fetch) the instructions from the computer-readable medium and execute the instructions for carrying out the described embodiments. Suitable storage formats include one or more of an electronic, magnetic, optical, and electromagnetic formats. A non-exhaustive list of exemplary computer-readable medium includes: a portable computer diskette; a random-access memory (RAM); a read-only memory (ROM); an erasable programmable read only memory (EPROM); a flash memory device; and optical storage devices, including a portable compact disc (CD), a portable digital video disc (DVD), and the like.

It should be understood that the arrangement of components illustrated in the attached Figures are for illustrative purposes and that other arrangements are possible. For example, one or more of the elements described herein may be realized, in whole or in part, as an electronic hardware component. The elements may be implemented in software, hardware, or a combination of software and hardware. Moreover, some or all of these other elements may be combined, some may be omitted altogether, and additional components may be added while still achieving the functionality described herein. Thus, the subject matter described herein may be embodied in many different variations, and all such variations are contemplated to be within the scope of the claims.

To facilitate an understanding of the subject matter described herein, many aspects are described in terms of sequences of actions. It will be recognized by those skilled in the art that the various actions may be performed by specialized circuits or circuitry, by program instructions being executed by one or more processors, or by a combination of both. The description herein of any sequence of actions is not intended to imply that the specific order described for performing that sequence must be followed. All methods described herein may be performed in any suitable order unless otherwise indicated herein or otherwise clearly contradicted by context.

The use of the terms “a” and “an” and “the” and similar references in the context of describing the subject matter (particularly in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. Furthermore, the foregoing description is for the purpose of illustration only, and not for the purpose of limitation, as the scope of protection sought is defined by the claims as set forth hereinafter together with any equivalents thereof. The use of any and all examples, or exemplary language (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions that bring about that result. No language in the specification should be construed as indicating any non-claimed element as essential to the practice of the invention as claimed.

1. A method for thermal management in an electronic device through fan control, comprising:
configuring one or more fans in the electronic device to operate in an intermittent mode, wherein in the intermittent mode, the one or more fans are sequentially powered in an intermittent manner;
based on detecting an overheat event in the electronic device, adjusting the one or more fans in the intermittent mode to enhance a cooling effect; and
based on the overheat event being resolved, controlling the one or more fans to return to the intermittent mode.

2. The method of claim 1, further comprising:
determining a power source between a main power and an auxiliary power for the electronic device;
based on determining the main power as the power source, configuring the one or more fans to operate in an intermittent mode associated with the main power; or
based on determining the auxiliary power as the power source, configuring the one or more fans to operate in an intermittent mode associated with the auxiliary power.

3. The method of claim 1, further comprising:
detecting, in the electronic device, a region associated with the overheat event, the region corresponding to at least one first fan of the one or more fans; and
switching the at least one first fan from the intermittent mode to a second intermittent mode, or switching the at least one first fan from the intermittent mode to a continuous power supply mode.

4. The method of claim 3, further comprising:
determining at least one second fan of the one or more fans, wherein the at least one second fan is located in a region surrounding the at least one first fan; and
adjusting the at least one second fan in a corresponding intermittent mode to enhance the cooling effect in the detected region.

5. The method of claim 1, further comprising:
based on determining that the electronic device currently operating in peak time, switching all fans in the one or more fans from the intermittent mode to a continuous power supply mode.

6. The method of claim 5, wherein the peak time is dynamically updated based on learning operational patterns of the electronic device.

7. The method of claim 1, wherein the intermittent mode is a default intermittent mode associated with an operating status of the electronic device,
wherein the operating status is active or idle, and
wherein the default intermittent mode associated with the operating status of the electronic device is dynamically updated based on learning operational patterns of the electronic device.

8. The method of claim 1, wherein adjusting the one or more fans in the intermittent mode to enhance the cooling effect further comprises:
determining an urgency and severity of the overheat event; and
determining, based on the urgency and severity, a cooling measure among a plurality of cooling measures.

9. The method of claim 8, wherein the plurality of cooling measures comprises:
switching at least one fan of the one or more fans from the intermittent mode to another intermittent mode;
switching at least one fan of the one or more fans from the intermittent mode to a continuous power supply mode; and
switching all fans in the one or more fans from the intermittent mode to the continuous power supply mode.

10. The method of claim 1, further comprising:
initiating a fan control system during power-on of the electronic device; and
loading settings associated with the intermittent mode.

11. A system for thermal management in an electronic device, comprising:
one or more fans; and
a controller configured to:
configure the one or more fans in the electronic device to operate in an intermittent mode, wherein in the intermittent mode, the one or more fans are sequentially powered in an intermittent manner;
based on detecting an overheat event in the electronic device, adjust the one or more fans in the intermittent mode to enhance a cooling effect; and
based on the overheat event being resolved, control the one or more fans to return to the intermittent mode.

12. The system of claim 11, wherein the controller is further configured to:
determine a power source between a main power and an auxiliary power for the electronic device;
based on determining the main power as the power source, configure the one or more fans to operate in an intermittent mode associated with the main power; or
based on determining the auxiliary power as the power source, configure the one or more fans to operate in an intermittent mode associated with the auxiliary power.

13. The system of claim 11, wherein the controller is further configured to:
detect, in the electronic device, a region associated with the overheat event, the region corresponding to at least one first fan of the one or more fans; and
switch the at least one first fan from the intermittent mode to a second intermittent mode, or switch the at least one first fan from the intermittent mode to a continuous power supply mode.

14. The met system hod of claim 13, wherein the controller is further configured to:
determine at least one second fan of the one or more fans, wherein the at least one second fan is located in a region surrounding the at least one first fan; and
adjust the at least one second fan in a corresponding intermittent mode to enhance the cooling effect in the detected region.

15. The system of claim 11, wherein the controller is further configured to:
based on determining that the electronic device currently operating in peak time, switch all fans in the one or more fans from the intermittent mode to a continuous power supply mode.

16. The system of claim 15, wherein the peak time is dynamically updated based on learning operational patterns of the electronic device.

17. The system of claim 11, wherein the intermittent mode is a default intermittent mode associated with an operating status of the electronic device,
wherein the operating status is active or idle, and
wherein the default intermittent mode associated with the operating status of the electronic device is dynamically updated based on learning operational patterns of the electronic device.

18. The system of claim 11, wherein adjusting the one or more fans in the intermittent mode to enhance the cooling effect further comprises:
determining an urgency and severity of the overheat event; and
determining, based on the urgency and severity, a cooling measure among a plurality of cooling measures.

19. The system of claim 18, wherein the plurality of cooling measures comprises:
switching at least one fan of the one or more fans from the intermittent mode to another intermittent mode;
switching at least one fan of the one or more fans from the intermittent mode to a continuous power supply mode; and
switching all fans in the one or more fans from the intermittent mode to the continuous power supply mode.

20. A non-transitory computer-readable medium having stored thereon a set of instructions for thermal management in an electronic device, which if performed by one or more processors, cause the one or more processors to perform:
configuring one or more fans in the electronic device to operate in an intermittent mode, wherein in the intermittent mode, the one or more fans are sequentially powered in an intermittent manner;
based on detecting an overheat event in the electronic device, adjusting the one or more fans in the intermittent mode to enhance a cooling effect; and
based on the overheat event being resolved, controlling the one or more fans to return to the intermittent mode.
